(19) United States
(12) Patent Application Publication
(10) Pub. No.: US 2025/0029904 A1
(43) Pub. Date: Jan. 23, 2025

(54) SEMICONDUCTOR FRAME AND SEMICONDUCTOR PACKAGE INCLUDING THE SAME

(71) Applicant: SAMSUNG ELECTRO-MECHANICS CO., LTD., Suwon-si (KR)

(72) Inventors: Sijoong YANG, Suwon-si (KR); Joon Seok CHAE, Suwon-si (KR); Dongsoon WOO, Suwon-si (KR); Daeyoung CHOI, Suwon-si (KR); Taeseok KO, Suwon-si (KR)

(73) Assignee: SAMSUNG ELECTRO-MECHANICS CO., LTD., Suwon-si (KR)

(21) Appl. No.: 18/664,941

(22) Filed: May 15, 2024

(30) Foreign Application Priority Data
Jul. 17, 2023 (KR) 10-2023-0092613

(51) Int. Cl. H01L 23/495; H01L 23/31

(52) U.S. Cl. CPC H01L 23/49586; H01L 23/3107; H01L 23/49537; H01L 23/49582

(57) ABSTRACT

A semiconductor package is provided. The semiconductor package includes a first semiconductor frame that includes a first lead frame and a first insulating layer disposed below the first lead frame; a second semiconductor frame that includes a second lead frame that faces the first lead frame and a second insulating layer disposed on the second lead frame; a semiconductor element that is disposed between the first semiconductor frame and the second semiconductor frame; and a molding portion that surrounds and seals at least a portion of the first semiconductor frame, at least a portion of the second semiconductor frame, and the semiconductor element.

### CROSS-REFERENCE TO RELATED APPLICATIONS

This application claims the benefit under 35 USC § 119 (a) of Korean Patent Application No. 10-2023-0092613 filed on Jul. 17, 2023, in the Korean Intellectual Property Office, the entire disclosure of which is incorporated herein by reference for all purposes.

### BACKGROUND

### 1. Field

The following description relates to a semiconductor frame and a semiconductor

package including the same.

### 2. Description of Related Art

As semiconductor devices develop, a highly integrated semiconductor package is being produced.

If heat is internally generated as a semiconductor element included in the semiconductor package operates and the internal heat is not dissipated externally, a temperature of the semiconductor element may increase and a failure rate of the element may increase.

Particularly, since a power semiconductor package may be driven using a high voltage and a high current, the heat generated when the element is driven increases. Performance of a power semiconductor element may be deteriorated and energy loss may occur or an insulating layer inside the power semiconductor may be destroyed so that reliability is lowered due to the heat generated when the power semiconductor package is driven.

On the other hand, it is beneficial to maintain thermal durability along with a physical strength of a support substrate that supports the semiconductor element within the semiconductor package, and at the same time, an effort is needed to prevent a complicated manufacturing process or a defect such as disconnection of a connection portion or the like.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a semiconductor frame includes a lead frame that includes a mounting portion configured to mount a semiconductor element, a wiring portion spaced apart from the mounting portion, and a lead-out portion that extends from the wiring portion; and an insulating layer that overlaps the mounting portion of the lead frame, and is disposed in a nonoverlapping manner with regard to the lead-out portion of the lead frame.

The semiconductor frame may further include a protective layer that overlaps the insulating layer, wherein the insulating layer may be disposed between the lead frame and the protective layer.

The insulating layer may include polyimide, and the protective layer may include a metal material.

The protective layer may include a metal foil.

A thickness of the insulating layer may be substantially equal to or greater than a thickness of the protective layer.

The protective layer may include a copper clad laminate.

A thickness of the protective layer may be substantially equal to or greater than a thickness of the insulating layer.

The insulating layer may include a ceramic material.

In a general aspect, a semiconductor package includes a first semiconductor frame comprising a first lead frame and a first insulating layer disposed below the first lead frame; a second semiconductor frame comprising a second lead frame that faces the first lead frame, and a second insulating layer disposed on the second lead frame; a semiconductor element disposed between the first semiconductor frame and the second semiconductor frame; and a molding portion that surrounds and seals at least a portion of the first semiconductor frame, at least a portion of the second semiconductor frame, and the semiconductor element.

The first lead frame may include a mounting portion configured to mount the semiconductor element, a wiring portion spaced apart from the mounting portion, and a lead-out portion that extends from the wiring portion, and wherein the first insulating layer and the second insulating layer may be disposed to overlap the mounting portion of the first lead frame, and are disposed in a nonoverlapping manner with regard to the lead-out portion of the first lead frame.

The semiconductor package may further include a first protective layer disposed below the first insulating layer; and a second protective layer disposed on the second insulating layer.

Each of the first insulating layer and the second insulating layer may include polyimide, and each of the first protective layer and the second protective layer may include a metal material.

A surface of the first protective layer may be exposed to an external environment without being surrounded by the molding portion.

Each of the first protective layer and the second protective layer may include a metal foil.

Thicknesses of the first insulating layer and the second insulating layer may be substantially equal to or greater than thicknesses of the first protective layer and the second protective layer.

Each of the first protective layer and the second protective layer may include a copper clad laminate.

Thicknesses of the first protective layer and the second protective layer may be substantially equal to or greater than thicknesses of the first insulating layer and the second insulating layer.

Each of the first insulating layer and the second insulating layer may include a ceramic material.

A surface of the first protective layer may be exposed to an external environment without being surrounded by the molding portion.

The lead-out portion may be exposed to the external environment without being surrounded by the molding portion.

Other features and aspects will be apparent from the following detailed description, the drawings, and the claims.

### BRIEF DESCRIPTION OF DRAWINGS

FIG. 1 illustrates an exploded perspective view of an example semiconductor frame, in accordance with one or more embodiments.

FIG. 2 illustrates an exploded perspective view of an example semiconductor frame, in accordance with one or more embodiments.

FIG. 3 illustrates an exploded perspective view of an example semiconductor frame, in accordance with one or more embodiments.

FIG. 4 illustrates a perspective view of an example semiconductor package, in accordance with one or more embodiments.

FIG. 5 illustrates a cross-sectional view cut along a line I-I′ of FIG. 4.

FIG. 6 illustrates a cross-sectional view of an example semiconductor package, in accordance with one or more embodiments.

FIG. 7 illustrates a cross-sectional view of an example semiconductor package, in accordance with one or more embodiments.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, a pattern, a via, a plane, a line, and an electrical connection structure may include a metallic material (e.g., a conductive material such as copper (Cu), aluminum (AI), silver (Ag), tin (Sn), gold (Au), nickel (Ni), lead (Pb), titanium (Ti), an alloy thereof, or the like), and may be formed according to a plating method such as chemical vapor deposition (CVD), physical vapor deposition (PVD), sputtering, a subtractive process, an additive process, a semi-additive process (SAP), a modified semi-additive process (MSAP), or the like, but this is not restrictive.

Throughout the one or more examples, a dielectric layer and/or an insulating layer may be implemented with a thermosetting resin such as FR4, a liquid crystal polymer (LCP), a lower temperature co-fired ceramic (LTCC), or an epoxy resin, a thermoplastic resin such as polyimide, a resin formed by impregnating the thermosetting resin and the thermoplastic resin in a core material such as a glass fiber (or a glass cloth or a glass fabric) with an inorganic filler, a prepreg, an Ajinomoto build-up film (ABF), FR-4, bismaleimide triazine (BT), a photoimageable dielectric (PID) resin, a typical copper clad laminate (CCL), a glass, a ceramic-based insulating material, or the like.

Throughout the one or more examples, a radio frequency (RF) signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a semiconductor frame that enables heat dissipation inside a semiconductor package, may not complicate a manufacturing process, and may support a semiconductor package element well, and a semiconductor package including the same.

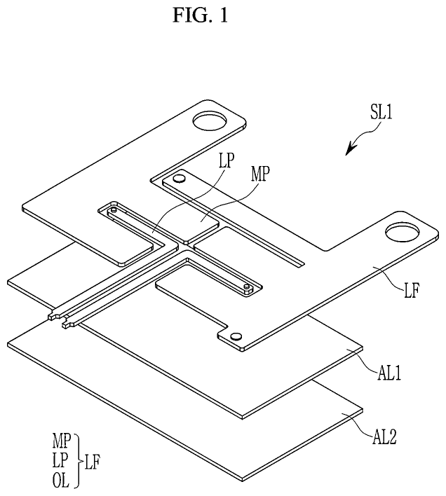

Referring to FIG. 1, an example semiconductor frame, in accordance with one or more embodiments, will be described. FIG. 1 is an exploded perspective view of an example semiconductor frame, in accordance with one or more embodiments.

Referring to FIG. 1, the semiconductor frame SL1, in accordance with one or more embodiments, may include a base frame LF at or on which a semiconductor element is installed, an insulating layer AL1 disposed below the base frame LF and overlapping at least a portion of the base frame LF, and a protective layer AL2, disposed below the insulating layer AL1, and overlapping at least a portion of the insulating layer AL1.

In an example, the base frame LF may be a lead frame. The base frame LF may include a mounting portion MP on which the semiconductor element is installed, a wiring portion LP spaced apart from the mounting portion MP, and a lead-out portion OL that extends from the wiring portion LP to the outside to receive a signal from the outside.

In an example, the base frame LF may include a metal material, and may be made of a single layer. In a non-limited example, the base frame LF may include at least one of copper (Cu), nickel (Ni), and iron (Fe). However, the embodiment is not limited thereto.

The insulating layer AL1 may overlap the mounting portion MP of the base frame LF, and may not overlap the lead-out portion OL of the base frame LF.

The insulating layer AL1 may include an insulating material, and the insulating layer AL1 may have a high dielectric constant and high thermal conductivity. In an example, the insulating layer AL1 may include polyimide. However, the embodiment is not limited thereto.

The insulating layer AL1 may transfer heat generated during an operation of the semiconductor element installed at the base frame LF to the outside.

In an example, the protective layer AL2 may overlap the insulating layer AL1.

The protective layer AL2 may include a metal, and in an example, the metal may be a metal foil including at least one of copper (Cu) and aluminum (AI). However, the embodiment is not limited thereto.

The protective layer AL2 may protect the insulating layer AL1, and may increase the transfer of heat from the insulating layer AL1, and may allow heat generated or collected in the insulating layer AL1 to be easily transferred to the outside.

In an example, a thickness of the insulating layer AL1 and a thickness of the protective layer AL2 may be substantially the same, or, in an example, the thickness of the insulating layer AL1 may be greater than the thickness of the protective layer AL2. However, the embodiments are not limited thereto.

The insulating layer AL1 may support the base frame LF, and may prevent warpage of the base frame LF.

The mounting portion MP and the wiring portion LP of the base frame LF may be supported by being attached to the insulating layer AL1 using an adhesive or a heat compression method. However, the embodiment is not limited thereto.

The lead-out portion OL that extends from the wiring portion LP may not be separated from the insulating layer AL1 together with the wiring portion LP that is supported by being attached to the insulating layer AL1.

If the semiconductor element mounted on the mounting portion MP of the semiconductor frame SL1 is an electric power semiconductor element, the electric power semiconductor element may be heated in a process of outputting electric power in which the electric power semiconductor element is repeatedly turned on and off so that performance of the electric power semiconductor element deteriorates. Typically, the electric power semiconductor element may be mounted on a mounting substrate in which a metal layer such as copper and a metal circuit layer are stacked on both surfaces of a substrate layer including a ceramic-based alumina material. However, as a capacity of the electric power semiconductor element increases, a size of the mounting substrate also increases. Thus, a manufacturing process of the mounting substrate including a plurality of layers may be complex, a manufacturing cost may increase, and a defect such as warpage or the like may occur in the mounting substrate.

However, the example semiconductor frame SL1, in accordance with one or more embodiments, may include the base frame LF at which the semiconductor element is installed that is made of a metal layer, the insulating layer AL1 overlapping the base frame LF, and the protective layer AL2 overlapping the insulating layer AL1, and the base frame LF may be a lead frame. Therefore, the semiconductor element may be mounted on the base frame LF that is the lead frame without a complicated process of forming the mounting substrate, so that a manufacturing process may be simple and an increase in a manufacturing cost may be prevented. Further, heat generated from the semiconductor element may be easily transferred to the outside through the insulating layer AL1 and the protective layer AL2 so that it is possible to prevent performance degradation of the semiconductor element due to internal heat and warpage of the base frame LF.

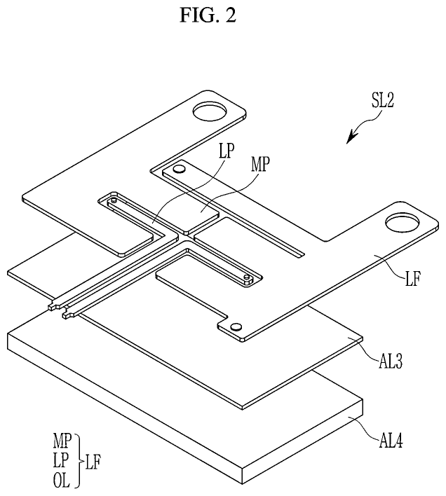

Referring to FIG. 2, an example semiconductor frame, in accordance with one or more embodiments, will be described. FIG. 2 illustrates an exploded perspective view of the example semiconductor package, in accordance with one or more embodiments.

Referring to FIG. 2, the semiconductor frame SL2, in accordance with one or more embodiments, may include the base frame LF on which the semiconductor element is installed, an insulating layer AL3 disposed below the base frame LF and overlapping at least a portion of the base frame LF, and a protective layer AL4 disposed below the insulating layer AL3 and overlapping at least a portion of the insulating layer AL3.

In an example, the base frame LF may be a lead frame. The base frame LF may include the mounting portion MP on which the semiconductor element is installed, the wiring portion LP spaced apart from the mounting portion MP, and the lead-out portion OL that extends from the wiring portion LP to the outside to receive a signal from the outside.

In an example, the base frame LF may include a metal, and may be made of a single layer. In a non-limited example, the base frame LF may include at least one of copper (Cu), nickel (Ni), and iron (Fe). However, the embodiment is not limited thereto.

The insulating layer AL3 may overlap the mounting portion MP of the base frame LF, and may not overlap the lead-out portion OL of the base frame LF.

The insulating layer AL3 may include an insulating material, and the insulating layer AL3 may have a high dielectric constant and high thermal conductivity. In an example, the insulating layer AL3 may include polyimide. However, the embodiment is not limited thereto.

The insulating layer AL3 may transfer heat generated during an operation of the semiconductor element installed at the base frame LF to the outside.

The insulating layer AL3 may support the base frame LF, and may prevent warpage of the base frame LF.

The mounting portion MP and the wiring portion LP of the base frame LF may be supported by being attached to the insulating layer AL3 using an adhesive or a heat compression method. However, the embodiment is not limited thereto.

The lead-out portion OL that extends from the wiring portion LP may not be separated from the insulating layer AL3 together with the wiring portion LP that is supported by being attached to the insulating layer AL3.

In an example, the protective layer AL4 may overlap the insulating layer AL3.

In an example, the protective layer AL4 may include a metal material. In a non-limited example, the protective layer AL4 may be a copper clad laminate (CCL), and may include at least one of copper (Cu) and aluminum (Al). However, the embodiment is not limited thereto.

The protective layer AL4 may protect the insulating layer AL3 and may increase the transfer of heat from the insulating layer AL3, and may allow heat generated or collected in the insulating layer AL3 to be transferred to the outside. Additionally, the protective layer AL4 may prevent warpage of the base frame LF together with the insulating layer AL3.

In an example, a thickness of the protective layer AL4 may be substantially the same as, or greater than, a thickness of the insulating layer AL3, and may be about 1 to about 2 times the thickness of the insulating layer AL3. However, the embodiment is not limited thereto.

The semiconductor frame SL2, according to the embodiment may include the base frame LF on which the semiconductor element is installed that is made of a metal layer, the insulating layer AL3 overlapping the base frame LF, and the protective layer AL4 overlapping the insulating layer AL3, and the base frame LF may be a lead frame. Therefore, the semiconductor element may be mounted on the base frame LF that is the lead frame without a complicated process of forming the mounting substrate, so that a manufacturing process may be simple, and an increase in a manufacturing cost may be prevented. Further, heat generated from the semiconductor element may be easily transferred to the outside through the insulating layer AL3 and the protective layer AL4 so that it is possible to prevent performance degradation of the semiconductor element due to internal heat. Additionally, the insulating layer AL3 and the protective layer AL4 may prevent warpage of the base frame LF.

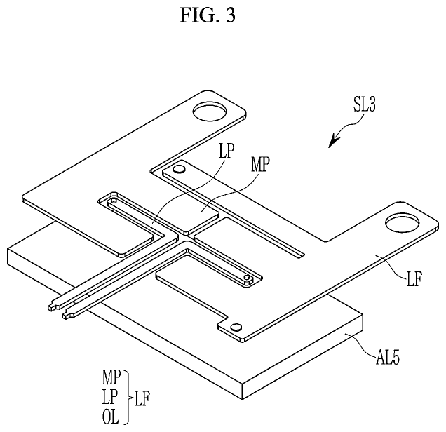

Referring to FIG. 3, a semiconductor frame, in accordance with one or more embodiments, will be described. FIG. 3 illustrates an exploded perspective view of the example semiconductor package, in accordance with one or more embodiments.

Referring to FIG. 3, the semiconductor frame SL3, in accordance with one or more embodiments, may include the base frame LF, on which the semiconductor element is installed, and an insulating layer AL5 disposed below the base frame LF and overlapping at least a portion of the base frame LF.

In an example, the base frame LF may be a lead frame. The base frame LF may include the mounting portion MP on which the semiconductor element is installed, the wiring portion LP spaced apart from the mounting portion MP, and the lead-out portion OL that extends from the wiring portion LP to the outside to receive a signal from the outside.

In an example, the base frame LF may include a metal material, and may be made of a single layer. In a non-limited example, the base frame LF may include at least one of copper (Cu), nickel (Ni), and iron (Fe). However, the embodiment is not limited thereto.

In an example, the insulating layer AL5 may overlap the mounting portion MP of the base frame LF, and may not overlap the lead-out portion OL of the base frame LF.

In an example, the insulating layer AL5 may include a ceramic material. However, the examples are not limited thereto.

The insulating layer AL5 may transfer heat generated during an operation of the semiconductor element installed on the base frame LF to the outside, may support the base frame LF, and may prevent warpage of the base frame LF.

The mounting portion MP and the wiring portion LP of the base frame LF may be supported by being attached to the insulating layer AL5 using an adhesive or a heat compression method. However, the embodiment is not limited thereto.

The lead-out portion OL that extends from the wiring portion LP may not be separated from the insulating layer AL5 together with the wiring portion LP that is supported by being attached to the insulating layer AL5.

The semiconductor frame SL3 according to the embodiment may include the base frame LF on which the semiconductor element is installed that is made of a metal layer and the insulating layer AL5 overlapping the base frame LF, and the base frame LF may be a lead frame. Therefore, the semiconductor element may be mounted on the base frame LF that is the lead frame without a complicated process of forming the mounting substrate, so that a manufacturing process may be simple and an increase in a manufacturing cost may be prevented. Further, heat generated from the semiconductor element may be easily transferred to the outside through the insulating layer AL5 so that it is possible to prevent performance degradation of the semiconductor element due to internal heat.

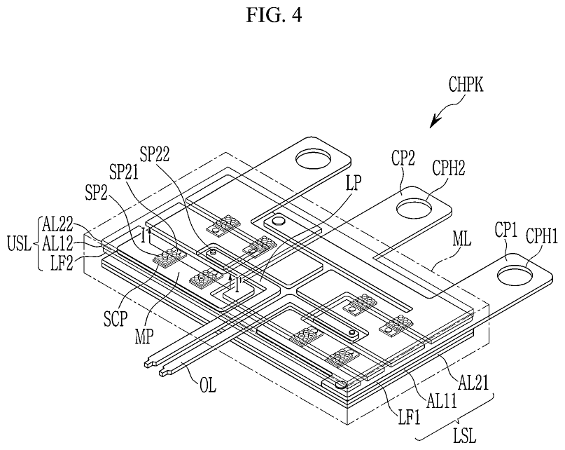

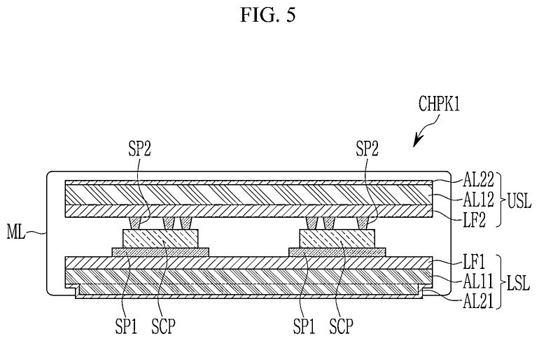

Referring to FIG. 4 and FIG. 5, an example semiconductor package CHPK, in accordance with one or more embodiments, will be described. FIG. 4 illustrates a perspective view of the example semiconductor package, in accordance with one or more embodiments, and FIG. 5 illustrates a cross-sectional view cut along a line I-I′ of FIG. 4.

Referring to FIG. 4 and FIG. 5, the example semiconductor package CHPK1, in accordance with one or more embodiments, may include a first semiconductor frame LSL and a second semiconductor frame USL that face each other, a plurality of semiconductor elements SCP disposed between the first semiconductor frame LSL and the second semiconductor frame USL, and a molding portion ML that seals the plurality of semiconductor elements SCP.

The first semiconductor frame LSL may include a first base frame LF1, a first insulating layer AL11, and a first protective layer AL21.

The second semiconductor frame USL may include a second base frame LF2, a second insulating layer AL12, and a second protective layer AL22.

The first base frame LF1 of the first semiconductor frame LSL may include a mounting portion MP on which the plurality of semiconductor elements SCP are installed, a wiring portion LP spaced apart from the mounting portion MP, a lead-out portion OL that extends from the wiring portion LP to the outside to receive a signal from the outside, a first connecting portion CP1 that extends outwards from the mounting portion MP to be assembled and connected to a semiconductor device, and a first connecting hole CPH1 formed on the first connecting portion CP1.

The first insulating layer AL11 and the first protective layer AL21 of the first semiconductor frame LSL may overlap the mounting portion MP of the first base frame LF1, and may not overlap the lead-out portion OL and the first connecting portion CP1 of the first base frame LF1.

The second base frame LF2 of the second semiconductor frame USL may include a mounting portion MP where the plurality of semiconductor elements SCP are mounted, a second connecting portion CP2 that extends outwards from the mounting portion MP to be assembled and connected to a semiconductor device, and a second connecting hole CPH2 formed on the second connecting portion CP2.

Each of the first base frame LF1 of the first semiconductor frame LSL and the second base frame LF2 of the second semiconductor frame USL may be a lead frame.

In an example, each of the first base frame LF1 and the second base frame LF2 may include a metal material, and may be made of a single layer. In an example, each of the first base frame LF1 and the second base frame LF2 may include at least one of copper (Cu), nickel (Ni), and iron (Fe). However, the embodiment is not limited thereto.

Each of the first insulating layer AL11 of the first semiconductor frame LSL and the second insulating layer AL12 of the second semiconductor frame USL may include an insulating material, and each of the first insulating layer AL11 and the second insulating layer AL12 may have a high dielectric constant and high thermal conductivity. In an example, each of the first insulating layer AL11 and the second insulating layer AL12 may include polyimide. However, the embodiment is not limited thereto.

The first insulating layer AL11 and the second insulating layer AL12 may transfer heat generated during operations of the plurality of semiconductor elements SCP installed between the first base frame LF1 and the second base frame LF2 to the outside.

Each of the first protective layer AL21 of the first semiconductor frame LSL and the second protective layer AL22 of the second semiconductor frame USL may include a metal material, and in an example, each of the first protective layer AL21 of the first semiconductor frame LSL and the second protective layer AL22 of the second semiconductor frame USL may be a metal foil including at least one of copper (Cu) and aluminum (AI). However, the embodiment is not limited thereto.

The first protective layer AL21 and the second protective layer AL22 may protect the first insulating layer AL11 and the second insulating layer AL12, and may increase the transfer of heat to the first insulating layer AL11 and the second insulating layer AL12 so that the heat generated by the semiconductor devices may be easily transferred to the outside.

In an example, thicknesses of the first insulating layer AL11 and the second insulating layer AL12 may be substantially the same as thicknesses of the first protective layer AL21 and the second protective layer AL22, or the thicknesses of the first insulating layer AL11 and the second insulating layer AL12 may be greater than the thicknesses of the first protective layer AL21 and the second protective layer AL22, but the embodiment is not limited thereto.

The first insulating layer AL11 and the second insulating layer AL12 may prevent warpages of the first base frame LF1 and the second base frame LF2.

The first insulating layer AL11 may support the first base frame LF1. In an example, the mounting portion MP and the wiring portion LP of the first base frame LF1 may be supported by being attached to the first insulating layer AL11 using an adhesive or a heat compression method. However, the embodiment is not limited thereto.

The lead-out portion OL that extends from the wiring portion LP may not be separated from the first insulating layer AL11 together with the wiring portion LP that is supported by being attached to the first insulating layer AL11.

Similarly, the second insulating layer AL12 may support the second base frame LF2.

The plurality of semiconductor elements SCP may be physically and electrically connected to the first base frame LF1 through a first contacting portion SP1, and may be physically and electrically connected to the second base frame LF2 through a second contacting portion SP2.

Each of the first contacting portion SP1 and the second contacting portion SP2 may include a solder paste. However, the embodiment is not limited thereto.

The plurality of semiconductor elements SCP may be installed at the first base frame LF1 through the first contacting portion SP1.

The plurality of semiconductor elements SCP may receive an electrical signal from the outside through the second contacting portion SP2, the first base frame LF1, and the second semiconductor frame USL. The second base frame LF2 may be connected to the wiring portion LP of the first base frame LF1 through a third contacting portion SP21, and the plurality of semiconductor elements SCP may be connected to the second base frame LF2 connected to the wiring portion LP of the first base frame LF1 through a fourth contacting portion SP22. However, the embodiment is not limited thereto.

In an example, the plurality of semiconductor elements SCP may be an electric power semiconductor element, the plurality of semiconductor elements SCP may receive a power signal applied to the lead-out portion OL of the first base frame LF1 through the third contacting portion SP21, the fourth contacting portion SP22, and the second base frame LF2, and the plurality of semiconductor elements SCP may receive a gate signal and a source signal from the second base frame LF2 through the second contacting portion SP2. However, the embodiment is not limited thereto.

The molding portion ML may surround and seal the first semiconductor frame LSL, the second semiconductor frame USL, and the plurality of semiconductor elements SCP disposed between the first semiconductor frame LSL and the second semiconductor frame USL.

The molding portion ML may protect the first semiconductor frame LSL, the second semiconductor frame USL, and the plurality of semiconductor elements SCP disposed between the first semiconductor frame LSL and the second semiconductor frame USL that are included therein.

The lead-out portion OL, the first connecting portion CP1, and the first connecting hole CPH1 of the first base frame LF1 and the second connecting portion CP2 and the second connecting hole CPH2 of the second base frame LF2 may be exposed to the outside of the molding portion ML.

Additionally, a surface of the first protective layer AL21 of the first semiconductor frame LSL may be exposed to the outside (or an external environment) without being surrounded by the molding portion ML.

The molding portion ML may include a polymer with excellent insulating and protective properties, and in an example, the molding portion ML may include an epoxy molding compound (EMC) or a polyimide-based material.

In the example semiconductor package CHPK1, in accordance with one or more embodiments, the plurality of semiconductor elements SCP may be installed between the first semiconductor frame LSL and the second semiconductor frame USL which face each other. The first semiconductor frame LSL and the second semiconductor frame USL may respectively include each of the first base frame LF1 and the second base frame LF2 made of a metal layer or material, the first insulating layer AL11 and the second insulating layer AL12 overlapping the first base frame LF1 and the second base frame LF2, and the first protective layer AL21 and the second protective layer AL22 which overlap the first insulating layer AL11 and the second insulating layer AL12, and each of the first base frame LF1 and the second base frame LF2 may be a lead frame.

Therefore, the plurality of semiconductor elements SCP may be respectively mounted on the first base frame LF1 and the second base frame LF2 that are the lead frames without a complicated process of forming a separate mounting substrate, so that a manufacturing process may be simple and an increase in a manufacturing cost may be prevented. Further, the plurality of semiconductor elements SCP may be installed between the first semiconductor frame LSL and the second semiconductor frame USL that face each other so that heat generated from the plurality of semiconductor elements SCP may be easily transferred to the outside through the first insulating layer AL11, the second insulating layer AL12, the first protective layer AL21, the second protective layer AL22, and lower portions and upper portions of the plurality of semiconductor elements SCP. Thus, it is possible to prevent performance degradation of the semiconductor elements SCP due to internal heat and warpage of the first base frame LF1 and the second base frame LF2.

Additionally, the surface of the first protective layer AL21 of the first semiconductor frame LSL may be exposed to the outside (or an external environment) without being surrounded by the molding portion ML, so that the heat generated from the plurality of semiconductor elements SCP may be easily transferred to the outside.

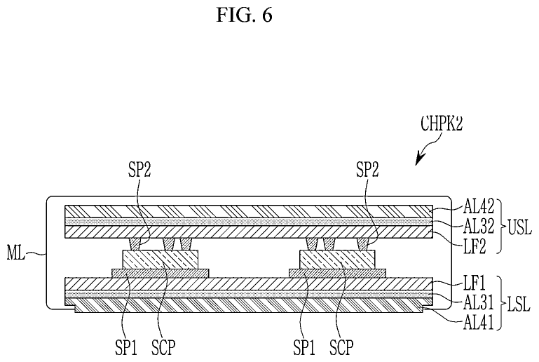

With reference to FIG. 6, an example semiconductor package CHPK2, in accordance with one or more embodiments, will be described. FIG. 6 illustrates a cross-sectional view of the example semiconductor package, in accordance with one or more embodiments.

Referring to FIG. 6, the example semiconductor package CHPK2, in accordance with one or more embodiments, is similar to the example semiconductor package CHPK1 according to the embodiment previously described with reference to FIGS. 4 and 5. A detailed description of the same constituent element is omitted.

Referring to FIG. 6, the example semiconductor package CHPK2, in accordance with one or more embodiments, may include a first semiconductor frame LSL and a second semiconductor frame USL which face each other, a plurality of semiconductor elements SCP disposed between the first semiconductor frame LSL and the second semiconductor frame USL, and a molding portion ML that seals the plurality of semiconductor elements SCP.

The first semiconductor frame LSL may include a first base frame LF1, a first insulating layer AL31, and a first protective layer AL41.

The second semiconductor frame USL may include a second base frame LF2, a second insulating layer AL32, and a second protective layer AL42.

Each of the first base frame LF1 of the first semiconductor frame LSL and the second base frame LF2 of the second semiconductor frame USL may be a lead frame.

In an example, each of the first base frame LF1 and the second base frame LF2 may include a metal material, and may be made of a single layer. In an example, each of the first base frame LF1 and the second base frame LF2 may include at least one of copper (Cu), nickel (Ni), and iron (Fe). However, the embodiment is not limited thereto.

Each of the first insulating layer AL31 of the first semiconductor frame LSL and the second insulating layer AL32 of the second semiconductor frame USL may include an insulating material, and each of the first insulating layer AL31 and the second insulating layer AL32 may have a high dielectric constant and high thermal conductivity. In an example, each of the first insulating layer AL31 and the second insulating layer AL32 may include polyimide. However, the embodiment is not limited thereto.

The first insulating layer AL31 and the second insulating layer AL32 may transfer heat generated during operations of the plurality of semiconductor elements SCP installed between the first base frame LF1 and the second base frame LF2 to the outside.

Each of the first protective layer AL41 of the first semiconductor frame LSL and the second protective layer AL42 of the second semiconductor frame USL may include a metal material, and in an example, each of the first protective layer AL41 and the second protective layer AL42 may be a copper clad laminate (CCL), and may include at least one of copper (Cu) and aluminum (Al). However, the embodiment is not limited thereto.

The first protective layer AL41 and the second protective layer AL42 may respectively protect the first insulating layer AL31 and the second insulating layer AL32, and may increase the transfer of heat from the first insulating layer AL31 and the second insulating layer AL32, and may allow heat generated or collected in the first insulating layer AL31 and the second insulating layer AL32 to be transferred to the outside.

In an example, thicknesses of the first protective layer AL41 and the second protective layer AL42 may be substantially the same as thicknesses of the first insulating layer AL31 and the second insulating layer AL32, or the thicknesses of the first protective layer AL41 and the second protective layer AL42 may be greater than the thicknesses of the first insulating layer AL31 and the second insulating layer AL32. Further, the thicknesses of the first protective layer AL41 and the second protective layer AL42 may be about 1 to about 2 times the thicknesses of the first insulating layer AL31 and the second insulating layer AL32. However, the embodiment is not limited thereto.

The first protective layer AL41 and the second protective layer AL42 may prevent warpages of the first base frame LF1 and the second base frame LF2 together with the first insulating layer AL31 and the second insulating layer AL32.

The first insulating layer AL31 may support the first base frame LF1. In an example, the mounting portion MP and the wiring portion LP of the first base frame LF1 may be supported by being attached to the first insulating layer AL31 using an adhesive or a heat compression method. However, the embodiment is not limited thereto.

The lead-out portion OL that extends from the wiring portion LP may not be separated from the first insulating layer AL31 together with the wiring portion LP that is supported by being attached to first insulating layer AL31.

Similarly, the second insulating layer AL32 may support the second base frame LF2.

The plurality of semiconductor elements SCP may be physically and electrically connected to the first base frame LF1 through a first contacting portion SP1, and may be physically and electrically connected to the second base frame LF2 through a second contacting portion SP2.

Each of the first contacting portion SP1 and the second contacting portion SP2 may include a solder paste.; However, the embodiment is not limited thereto.

The plurality of semiconductor elements SCP may receive an electrical signal applied to the first base frame LF1 and the second semiconductor frame USL through the first contacting portion SP1 and the second contacting portion SP2.

The molding portion ML may surround and seal the first semiconductor frame LSL, the second semiconductor frame USL, and the plurality of semiconductor elements SCP disposed between the first semiconductor frame LSL and the second semiconductor frame USL.

The molding portion ML may protect the first semiconductor frame LSL, the second semiconductor frame USL, and the plurality of semiconductor elements SCP disposed between the first semiconductor frame LSL and the second semiconductor frame USL that are included therein.

In an example, a surface of the first protective layer AL41 of the first semiconductor frame LSL may be exposed to the outside (or an external environment) without being surrounded by the molding portion ML.

The molding portion ML may include a polymer with excellent insulating and protective properties, and in an example, the molding portion ML may include an epoxy molding compound (EMC) or a polyimide-based material.

In the example semiconductor package CHPK2, in accordance with one or more embodiments, the plurality of semiconductor elements SCP may be installed between the first semiconductor frame LSL and the second semiconductor frame USL facing each other, the first semiconductor frame LSL and the second semiconductor frame USL may include each of the first base frame LF1 and the second base frame LF2 made of a metal layer, the first insulating layer AL31 and the second insulating layer AL32 overlapping the first base frame LF1 and the second base frame LF2, and the first protective layer AL41 and the second protective layer AL42 overlapping the first insulating layer AL31 and the second insulating layer AL32, and each of the first base frame LF1 and the second base frame LF2 may be a lead frame.

Therefore, the plurality of semiconductor elements SCP may be respectively mounted on the first base frame LF1 and the second base frame LF2 that are the lead frames without a complicated process of forming a separate mounting substrate, so that a manufacturing process may be simple and an increase in a manufacturing cost may be prevented.

Further, the plurality of semiconductor elements SCP may be installed between the first semiconductor frame LSL and the second semiconductor frame USL facing each other so that heat generated from the plurality of semiconductor elements SCP is easily transferred to the outside through the first insulating layer AL31, the second insulating layer AL32, the first protective layer AL41, the second protective layer AL42, and lower portions and upper portions of the plurality of semiconductor elements SCP. Thus, it is possible to prevent performance degradation of the semiconductor elements SCP due to internal heat and warpage of the first base frame LF1 and the second base frame LF2.

Additionally, the surface of the first protective layer AL41 of the first semiconductor frame LSL may be exposed to the outside without being surrounded by the molding portion ML, so that the heat generated from the plurality of semiconductor elements SCP is easily transferred to the outside.

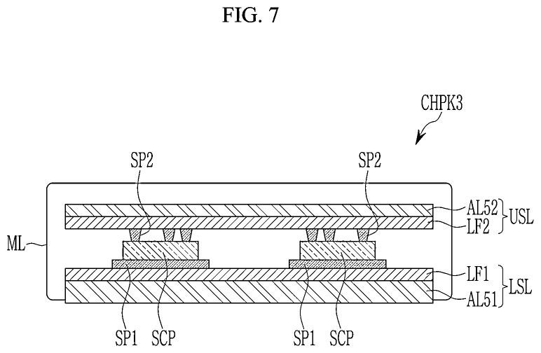

Referring to FIG. 7, an example semiconductor package CHPK3, in accordance with one or more embodiments, will be described. FIG. 7 illustrates a cross-sectional view of the example semiconductor package, in accordance with one or more embodiments.

Referring to FIG. 7, the example semiconductor package CHPK3, in accordance with one or more embodiments, may include a first semiconductor frame LSL and a second semiconductor frame USL that face each other, a plurality of semiconductor elements SCP disposed between the first semiconductor frame LSL and the second semiconductor frame USL, and a molding portion ML that seals the plurality of semiconductor elements SCP.

The first semiconductor frame LSL may include a first base frame LF1 and a first insulating layer AL51.

The second semiconductor frame USL may include a second base frame LF2 and a second insulating layer AL52.

Each of the first base frame LF1 of the first semiconductor frame LSL and the second base frame LF2 of the second semiconductor frame USL may be a lead frame.

In an example, each of the first base frame LF1 and the second base frame LF2 may include a metal material, and may be made of a single layer. In an example, each of the first base frame LF1 and the second base frame LF2 may include at least one of copper (Cu), nickel (Ni), and iron (Fe). However, the embodiment is not limited thereto.

The first insulating layer AL51 of the first semiconductor frame LSL and the second insulating layer AL52 of the second semiconductor frame USL may include a ceramic material. However, the embodiment is not limited thereto.

The first insulating layer AL51 and the second insulating layer AL52 may transfer heat generated during operations of the plurality of semiconductor elements SCP installed between the first base frame LF1 and the second base frame LF2 to the outside, may support the first base frame LF1 and the second base frame LF2, and may prevent warpages of the first base frame LF1 and the second base frame LF2.

The first insulating layer AL51 may support the first base frame LF1. In an example, the mounting portion MP and the wiring portion LP of the first base frame LF1 may be supported by being attached to the first insulating layer AL51 using an adhesive or a heat compression method. However, the embodiment is not limited thereto.

The lead-out portion OL that extends from the wiring portion LP may not be separated from the first insulating layer AL51 together with the wiring portion LP that is supported by being attached to first insulating layer AL51.

Similarly, the second insulating layer AL52 may support the second base frame LF2.

The plurality of semiconductor elements SCP may be physically and electrically connected to the first base frame LF1 through a first contacting portion SP1, and may be physically and electrically connected to the second base frame LF2 through a second contacting portion SP2.

Each of the first contacting portion SP1 and the second contacting portion SP2 may include a solder paste. However, the embodiment is not limited thereto.

The plurality of semiconductor elements SCP may receive an electrical signal applied to the first base frame LF1 and the second semiconductor frame USL through the first contacting portion SP1 and the second contacting portion SP2.

The molding portion ML may surround and seal the first semiconductor frame LSL, the second semiconductor frame USL, and the plurality of semiconductor elements SCP disposed between the first semiconductor frame LSL and the second semiconductor frame USL.

The molding portion ML may protect the first semiconductor frame LSL, the second semiconductor frame USL, and the plurality of semiconductor elements SCP disposed between the first semiconductor frame LSL and the second semiconductor frame USL that are included therein.

A surface of the first protective layer AL51 of the first semiconductor frame LSL may be exposed to the outside (or an external environment) without being surrounded by the molding portion ML.

The molding portion ML may include a polymer with excellent insulating and protective properties, and for example, the molding portion ML may include an epoxy molding compound (EMC) or a polyimide-based material.

In the example semiconductor package CHPK3, in accordance with one or more embodiments, the plurality of semiconductor elements SCP may be installed between the first semiconductor frame LSL and the second semiconductor frame USL facing each other, the first semiconductor frame LSL and the second semiconductor frame USL may include each of the first base frame LF1 and the second base frame LF2 made of a metal layer and the first insulating layer AL51 and the second insulating layer AL52 overlapping the first base frame LF1 and the second base frame LF2, and each of the first base frame LF1 and the second base frame LF2 may be a lead frame.

Therefore, the plurality of semiconductor elements SCP may be mounted on the first base frame LF1 and the second base frame LF2 that are the lead frames without a complicated process of forming a separate mounting substrate, so that a manufacturing process may be simple and an increase in a manufacturing cost may be prevented.

Further, the plurality of semiconductor elements SCP may be installed between the first semiconductor frame LSL and the second semiconductor frame USL facing each other so that heat generated from the plurality of semiconductor elements SCP is easily transferred to the outside through the first insulating layer AL51, the second insulating layer AL52, and lower portions and upper portions of the plurality of semiconductor elements SCP. Thus, it is possible to prevent performance degradation of the semiconductor elements SCP due to internal heat and warpage of the first base frame LF1 and the second base frame LF2.

Additionally, the surface of the first protective layer AL51 of the first semiconductor frame LSL may be exposed to the outside (or an external environment) without being surrounded by the molding portion ML, so that the heat generated from the plurality of semiconductor elements SCP may be easily transferred to the outside.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor frame, comprising:
a lead frame that comprises a mounting portion configured to mount a semiconductor element, a wiring portion spaced apart from the mounting portion, and a lead-out portion that extends from the wiring portion; and
an insulating layer that overlaps the mounting portion of the lead frame, and is disposed in a nonoverlapping manner with regard to the lead-out portion of the lead frame.

2. The semiconductor frame of claim 1, further comprising a protective layer that overlaps the insulating layer,
wherein the insulating layer is disposed between the lead frame and the protective layer.

3. The semiconductor frame of claim 2, wherein the insulating layer comprises polyimide, and the protective layer comprises a metal material.

4. The semiconductor frame of claim 3, wherein the protective layer comprises a metal foil.

5. The semiconductor frame of claim 4, wherein a thickness of the insulating layer is substantially equal to or greater than a thickness of the protective layer.

6. The semiconductor frame of claim 3, wherein the protective layer comprises a copper clad laminate.

7. The semiconductor frame of claim 6, wherein a thickness of the protective layer is substantially equal to or greater than a thickness of the insulating layer.

8. The semiconductor frame of claim 1, wherein the insulating layer comprises a ceramic material.

9. A semiconductor package, comprising:
a first semiconductor frame comprising a first lead frame and a first insulating layer disposed below the first lead frame;
a second semiconductor frame comprising a second lead frame that faces the first lead frame, and a second insulating layer disposed on the second lead frame;
a semiconductor element disposed between the first semiconductor frame and the second semiconductor frame; and
a molding portion that surrounds and seals at least a portion of the first semiconductor frame, at least a portion of the second semiconductor frame, and the semiconductor element.

10. The semiconductor package of claim 9, wherein the first lead frame comprises a mounting portion configured to mount the semiconductor element, a wiring portion spaced apart from the mounting portion, and a lead-out portion that extends from the wiring portion, and
wherein the first insulating layer and the second insulating layer are disposed to overlap the mounting portion of the first lead frame, and are disposed in a nonoverlapping manner with regard to the lead-out portion of the first lead frame.

11. The semiconductor package of claim 9, further comprising:
a first protective layer disposed below the first insulating layer; and
a second protective layer disposed on the second insulating layer.

12. The semiconductor package of claim 11, wherein each of the first insulating layer and the second insulating layer comprises polyimide, and each of the first protective layer and the second protective layer comprises a metal material.

13. The semiconductor package of claim 12, wherein a surface of the first protective layer is exposed to an external environment without being surrounded by the molding portion.

14. The semiconductor package of claim 13, wherein each of the first protective layer and the second protective layer comprises a metal foil.

15. The semiconductor package of claim 14, wherein thicknesses of the first insulating layer and the second insulating layer are substantially equal to or greater than thicknesses of the first protective layer and the second protective layer.

16. The semiconductor package of claim 13, wherein each of the first protective layer and the second protective layer comprises a copper clad laminate.

17. The semiconductor package of claim 16, wherein thicknesses of the first protective layer and the second protective layer are substantially equal to or greater than thicknesses of the first insulating layer and the second insulating layer.

18. The semiconductor package of claim 9, wherein each of the first insulating layer and the second insulating layer comprises a ceramic material.

19. The semiconductor package of claim 18, wherein a surface of the first protective layer is exposed to an external environment without being surrounded by the molding portion.

20. The semiconductor package of claim 19, wherein the lead-out portion is exposed to the external environment without being surrounded by the molding portion.
